(19) United States
(12) Patent Application Publication
(10) Pub. No.: US 2009/0325389 A1
(43) Pub. Date: Dec. 31, 2009

(54) Substrate processing apparatus and manufacturing method of semiconductor device

(75) Inventors: Yuji Takebayashi, Toyama-shi (JP); Masanori Sakai, Takaoka-shi (JP); Tsutomu Kato, Takaoka-shi (JP); Kenji Ono, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/457,584

(22) Filed: Jun. 16, 2009

(30) Foreign Application Priority Data
Jun. 16, 2008 (JP) 2008-156499
May 11, 2009 (JP) 2009-114861

(51) Int. Cl. H01L 21/18; B05C 11/00

(52) U.S. Cl. 438/758; 118/712; 257/E21.085

(57) ABSTRACT

To grasp an accumulation state of residual matters inside of a vaporizer without decomposing the vaporizer, and grasp the timing of performing maintenance to the inside of the vaporizer in advance. A substrate processing apparatus of the present invention includes: a processing chamber in which substrates are contained; a vaporizer having a vaporizing space, for generating vaporized gas by vaporizing liquid source supplied into the vaporizing space; a liquid source supply system having a liquid source supply line for supplying the liquid source into the vaporizing space; a vaporized gas supply system having a vaporized gas supply line for supplying the vaporized gas into the processing chamber; an exhaust system for exhausting an atmosphere in the processing chamber; a pressure meter for measuring a pressure in the vaporizing space; a carrier gas supply system having a carrier gas supply line for supplying carrier gas into the vaporizing space; and a controller for judging a state of the vaporizer based on a measured value of the pressure meter when the carrier gas is supplied into the vaporizing space.

### BACKGROUND

1. Technical Field

The present invention relates to a substrate processing apparatus for processing substrates, and a manufacturing method of a semiconductor device having the steps of processing the substrates.

2. Description of Related Art

In a semiconductor device such as DRAM, with higher density has been pursued, a high dielectric constant film (High-k film) containing, for example, hafnium (Hf) element and zirconium (Zr) element has been used in recent years, as a gate insulating film and a capacitor insulating film. For example, this is because in a case of HfO₂ film of 1.6 nm, a high dielectric constant nearly equal to that of SiO₂ film of 4.5 nm can be obtained. In order to form the high dielectric film containing Hf element and Zr element, for example, ALD (Atomic Layer Deposition) method, etc, has been generally used, in which gas containing Hf element and Zr element and gas containing oxygen (O) element are alternately supplied onto a substrate such as a silicon wafer.

The gas containing Hf element and Zr element has been generated by vaporizing, for example organic compounds (liquid source) such as TEMAH (Hf[N(CH₃)CH₂CH₃]₄: tetrakisethylmethylaminohafnium) and TEMAZ(Zr[N(CH₃)CH₂CH₃]₄:tetrakisethylmethylaminozircomium), using a vaporizer. The vaporizer has a vaporizing space heated to a prescribed temperature atmosphere, so that gas is generated by vaporizing the liquid source supplied into the vaporizing space.

### SUMMARY OF THE INVENTION

The organic compounds (liquid source) such as TEMAH and TEMAZ generate residual matters containing a carbon compound when vaporizing these liquid sources in the vaporizer. Such residual matters are one of the factors of causing deterioration of production yield of a semiconductor device. For example, when the residual matters are accumulated in the vaporizer by repeatedly performing vaporization, inside of the vaporizer is clogged, thereby causing vaporization failure by boosting a pressure in the vaporizer, thus inviting insufficient flow rate of the gas supplied into the processing chamber. Also, the residual matters enter into a processing chamber together with the gas, and can be foreign matters that cause degradation of quality of processing substrates. Accordingly, when an accumulation amount of the residual matters is increased, maintenance needs to be performed to the inside of the vaporizer.

However, in a conventional substrate processing apparatus, it is difficult to grasp an accumulation state (clogging state) of the residual matters without decomposing the vaporizer. Therefore, timing of performing maintenance to the inside of the vaporizer is lost, thus inviting sudden reduction of the production yield in some cases.

An object of the present invention is to provide the substrate processing apparatus and the manufacturing method of a semiconductor device, capable of grasping the accumulation state of the residual matters in the vaporizer without decomposing the vaporizer, and capable of easily grasping the timing in advance, to perform maintenance to the inside of the vaporizer.

According to one of the aspects of the present invention, there is provided a substrate processing apparatus, including:

a processing chamber in which substrates are contained;

a vaporizer having a vaporizing space, for generating vaporized gas by vaporizing liquid source supplied into the vaporizing space;

a liquid source supply system having a liquid source supply line for supplying the liquid source into the vaporizing space;

a vaporized gas supply system having a vaporized gas supply line for supplying the vaporized gas into the processing chamber;

an exhaust system for exhausting an atmosphere in the processing chamber;

a pressure meter for measuring a pressure in the vaporizing space;

a carrier gas supply system having a carrier gas supply line for supplying carrier gas into the vaporizing space; and

a controller for judging a state of the vaporizer based on a measured value of the pressure meter when the carrier gas is supplied into the vaporizing space.

According to another aspect of the present invention, there is provided a manufacturing method of a semiconductor device, comprising the steps of:

forming a film by supplying vaporized gas generated by supplying liquid source into a vaporizing space, to substrates contained in a processing chamber; and

purging a vaporized space by supplying carrier gas into the vaporizing space, with no liquid source supplied into the vaporizing space,

with these steps alternately repeated, and

in each of the repeated step of purging vaporizing space, pressure in the vaporizing space is measured while supplying the carrier gas of the same flow rate into the vaporizing space, and when a measured value of the pressure is less than a prescribed pressure value, maintenance of the vaporizer is judged to be unnecessary, and when the measured value of the pressure is more than the prescribed pressure value, the maintenance of the vaporizer is judged to be necessary.

According to further another aspect of the present invention, there is provided a manufacturing method of a semiconductor device, including the steps of:

loading substrates into a processing chamber;

reducing pressure in the processing chamber;

increasing temperature of the substrates;

forming a film by supplying vaporized gas generated by supplying liquid source into a vaporizing space, to the substrates contained in the processing chamber;

increasing pressure in the processing chamber;

unloading the substrates to outside the processing chamber; and

measuring pressure in the vaporizing space while supplying carrier gas, with no liquid source supplied into the vaporizing space.

According to the substrate processing apparatus and the manufacturing method of the semiconductor device according to the present invention, the accumulation state of the residual matters in the vaporizer can be grasped without decomposing the vaporizer, and the timing of performing maintenance to the inside of the vaporizer can be grasped in advance.

### BRIEF DESCRIPTION OF THE DRAWINGS

FIG. 1 is a schematic block diagram of a substrate processing apparatus according to an embodiment of the present invention.

FIG. 2 is a schematic block diagram of a processing furnace provided in the substrate processing apparatus according to an embodiment of the present invention, wherein FIG. 2A shows a vertically sectional schematic view of the processing furnace, and FIG. 2B shows a horizontally sectional schematic view of the processing furnace, respectively.

FIG. 3 is a schematic block diagram of a vaporizer provided in the substrate processing apparatus according to an embodiment of the present invention.

FIG. 4 is a graph chart exemplifying a state of a pressure variation in a vaporizing space when the step of forming a film and the step of purging vaporizing space are alternately repeated.

FIG. 5 is a graph chart exemplifying a relation between the pressure variation in the vaporizing space and the vaporizer.

FIG. 6 is a flowchart showing the substrate processing step as an embodiment of the present invention.

### DESCRIPTION OF PREFERRED EMBODIMENT OF THE INVENTION

### (1) Structure of the Substrate Processing Apparatus

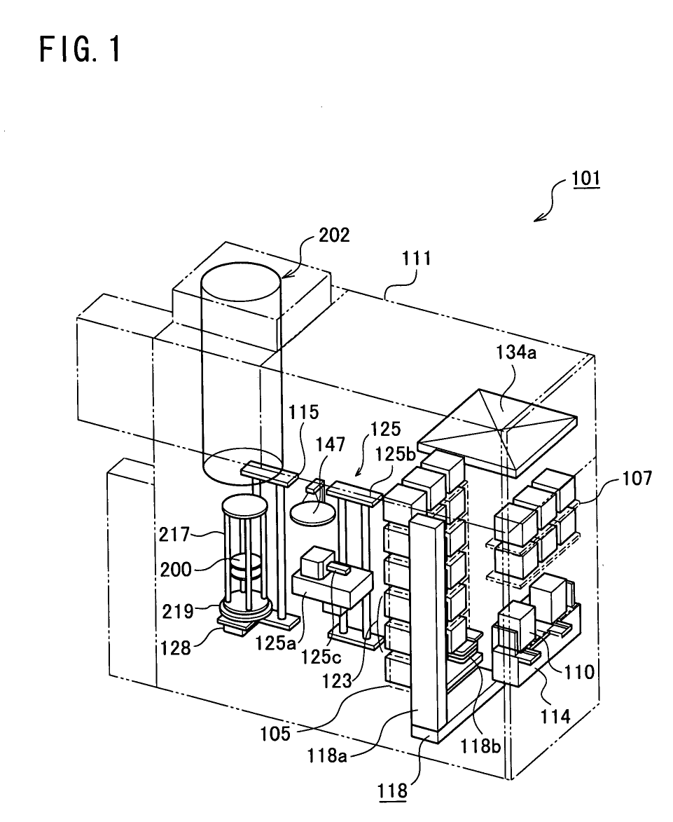

First, a constitutional example of a substrate processing apparatus 101 according to an embodiment of the present invention will be described, by using FIG. 1.

As shown in FIG. 1, the substrate processing apparatus 101 according to this embodiment includes a casing 111. In order to convey a wafer (substrate) 200 made of silicon, etc, into/out of the casing 111, a cassette 110, being a wafer carrier (substrate containing vessel), in which a plurality of wafers 200 are contained, is used. A cassette stage (substrate containing vessel transfer table) 114 is provided in a frontward part in the casing 111 (at the right side in the figure). The cassette 110 is placed on the cassette stage 114 by an in-step conveyance device not shown, and is unloaded to outside the casing 111 from the surface of the cassette stage 114.

The cassette 110 is placed on the cassette stage 114, so that the wafer 200 in the cassette 110 is set in a vertical posture and a wafer charging/discharging port of the cassette 110 is directed upward. The cassette stage 114 is constituted so that the cassette 110 can be rotated by 90° toward the backward of the casing 111, with the wafer 200 in the cassette 110 set in a horizontal posture, and the wafer charging/discharging port of the cassette 110 can be directed backward in the casing 111.

A cassette shelf (substrate containing vessel placement shelf) 105 is installed in approximately a laterally center part in the casing 111. The cassette shelf 105 is constituted, so that a plurality of cassettes 110 are stored in multiple stages and in multiple rows. A transfer shelf 123 storing the cassette 110, being a conveyance object of a wafer transfer mechanism 125 as will be described later, is provided in the cassette shelf 105. Further, a preliminary cassette shelf 107 is provided in an upper part of the cassette stage 114, so that the cassette 110 is preliminarily stored.

A cassette conveyance device (substrate containing vessel conveyance device) 118 is provided between the cassette stage 114 and the cassette shelf 105. The cassette conveyance device 118 includes a cassette elevator (substrate containing vessel elevation mechanism) 118a that can be elevated, with the cassette 110 held thereon, and a cassette conveyance mechanism (substrate containing vessel conveyance mechanism) 118b as a conveyance mechanism that can be moved horizontally, with the cassette 110 held thereon. By cooperative operation of these cassette elevator 118a and cassette conveyance mechanism 118b, the cassette 110 is conveyed among the cassette stage 114, the cassette shelf 105, the preliminary cassette shelf 107, and the transfer shelf 123.

The wafer transfer mechanism (substrate transfer mechanism) 125 is provided in a backward part of the cassette shelf 105. The wafer transfer mechanism 125 includes a wafer transfer device (substrate transfer device) 125a capable of horizontally rotating or linearly moving the wafer 200, and a wafer transfer device elevator (substrate transfer device elevation mechanism) 125b for elevating the wafer transfer device 125a. In addition, the wafer transfer device 125a includes a tweezer (substrate transferring jig) for holding the wafer 200 in a horizontal posture. By cooperative operation of these wafer transfer device 125a and wafer transfer device elevator 125b, the wafer is picked up from the cassette 110 on the transfer shelf 123, then is charged into a boat (substrate support member) 217 as will be described later or discharged from the boat 217, and is stored in the cassette 110 on the transfer shelf 123.

A processing furnace 202 is provided in the upper rear of the casing 111. An opening is formed on a lower end portion of the processing furnace 202, so that the opening is opened/closed by a furnace throat shutter (furnace throat open/close mechanism). Note that the structure of the processing furnace 202 will be described later.

A boat elevator (substrate support member elevation mechanism) 115, being an elevation mechanism for elevating the boat 217 and conveying it into/from the processing furnace 202, is provided in a lower part of the processing furnace 202. An arm 128, being a connection tool, is provided on an elevation table of the boat elevator 115. A seal cap 219 is provided on the arm 128 in a horizontal posture, which is a lid member for vertically supporting the boat 217 and air-tightly closing the lower end portion of the processing furnace 202 when the boat 217 is elevated by the boat elevator 115.

The boat 217 includes a plurality of holding members, so that a plurality of sheets of wafers 200 (for example, 50 to 150 sheets) are vertically arranged, with centers thereof aligned in a horizontal posture and held in multiple stages. Detailed structure of the boat 217 will be described later.

A clean unit 134a including a supply fan and a dust-proof filter is provided in an upper part of the cassette shelf 105. The clean unit 134a is constituted so that clean air, being cleaned atmosphere, flows through the casing 111.

Moreover, a clean unit (not shown) including the supply fan and the dust-proof filter so as to supply clean air, is installed at the left side end portion of the casing 111, being the opposite side to the side of the wafer transfer device elevator 125b and the boat elevator 115. The clean air blown out from the clan unit not shown flows around the wafer transfer device 125a and the boat 217, and thereafter is sucked into an exhaust device not shown, and exhausted to outside of the casing 111.

### (2) Operation of the Substrate Processing Apparatus

Next, an operation of the substrate processing apparatus 101 according to this embodiment will be described.

First, the cassette 110 is placed on the cassette stage 114, by an in-step conveyance apparatus not shown, so that the wafer 200 is set in a vertical posture and the wafer charging/discharging port of the cassette 110 is directed upward. Thereafter, the cassette 110 is rotated by 90° vertically directed backward of the casing 111, by the cassette stage 114. As a result, the wafer 200 in the cassette 110 is set in a horizontal posture, and the wafer charging/discharging port of the cassette 110 is directed backward in the casing 111.

The cassette 110 is automatically conveyed and transferred to a designated shelf position of the cassette shelf 105 or the preliminary cassette shelf 107 by the cassette conveyance device 118, which is then temporarily stored therein and thereafter is transferred to the transfer shelf 123 from the cassette shelf 105 or the preliminary cassette shelf 107 or is directly conveyed to the transfer shelf 123.

When the cassette 110 is transferred to the transfer shelf 123, the wafer 200 is picked up from the cassette 110 through the wafer charging/discharging port by a tweezer 125c of the wafer transfer device 125a, and by sequential operation of the wafer transfer device 125a and the wafer transfer device elevator 125b, the wafer 200 is charged into the boat 217 in the rear of the transfer chamber 124. The wafer transfer mechanism 125 that transfers the wafer 200 to the boat 217 is returned to the cassette 110, and charges the next wafer 200 into the boat 217.

When previously designated numbers of wafers 200 are charged into the boat 217, the lower end portion of the processing furnace 202 closed by the furnace throat shutter 147 is opened by the furnace throat shutter 147. Subsequently, by elevating the seal cap 219 by the boat elevator 115, the boat 217 holding wafer 200 group is loaded into the processing furnace 202 (loading). After loading, arbitrary processing is applied to the wafer 200 in the processing furnace 202. Such processing will be described later. After processing, the wafer 200 and the cassette 110 are discharged to outside of the casing 111 by a reversed procedure to the aforementioned procedure.

### (3) Structure of the Processing Furnace

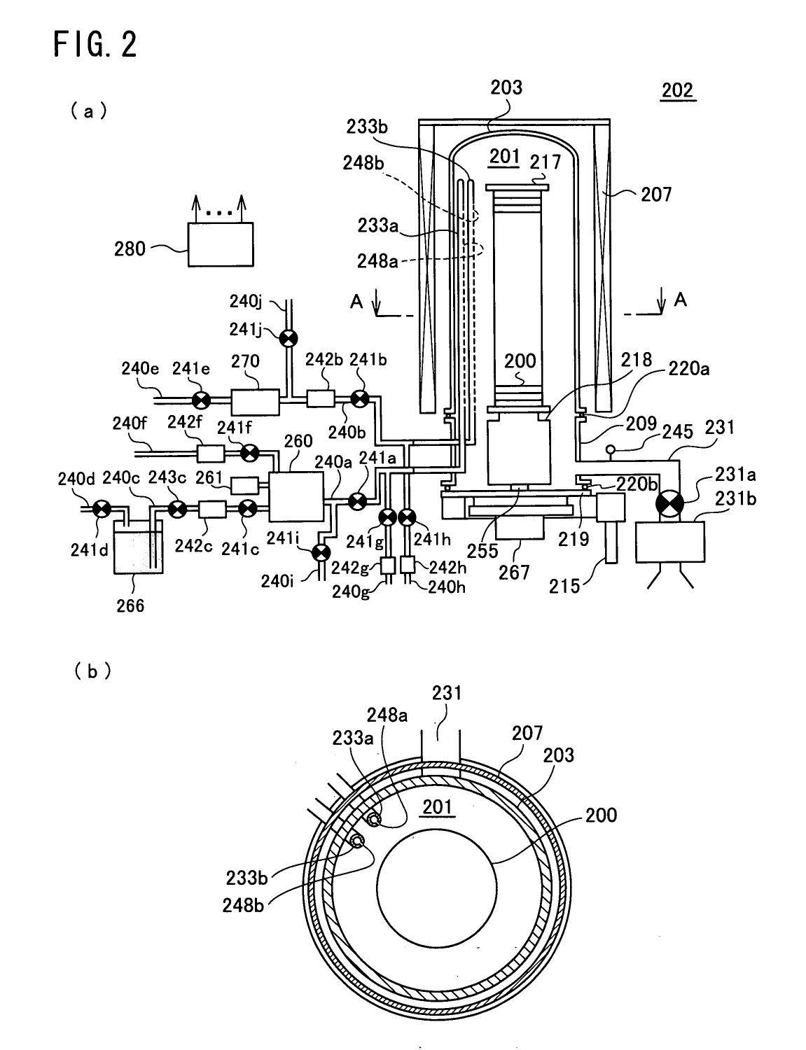

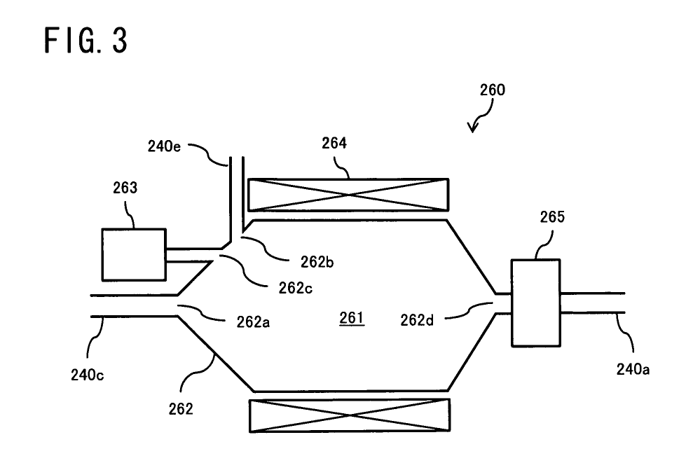

Subsequently, a structure of the processing furnace 202 according to an embodiment of the present invention will be described, with reference to the drawings. FIG. 2 is a schematic block diagram of the processing furnace 202 provided in the substrate processing apparatus according to an embodiment of the present invention, wherein FIG. 2A is a vertically sectional schematic view, and FIG. 2B shows a horizontally schematic view of the processing furnace 202 shown in FIG. 2A. FIG. 3 is a schematic block diagram of the vaporizer provided in the substrate processing apparatus according to an embodiment of the present invention.

### (Processing Chamber)

The processing furnace 202 according to an embodiment of the present invention has a reaction tube 203 and a manifold 209. The reaction tube 203 is made of a non-metal material having heat resistant property, such as quartz (SiO₂) and silicon carbide (SiC), and is formed into a cylindrical shape with an upper end portion closed and a lower end portion opened. The manifold 209 is made of a metal material such as SUS, and is formed into the cylindrical shape, with the upper end portion and the lower end portion opened. The reaction tube 203 is vertically supported from the lower end portion side by the manifold 209. The reaction tube 203 and the manifold 209 are concentrically disposed. The lower end portion of the manifold 209 is air-tightly sealed by the seal cap 219 when the aforementioned boat elevator 115 is elevated. A seal member 220 such as an O-ring for air-tightly sealing the inside of the processing chamber 201 is provided between the lower end portion of the manifold 209 and the seal cap 219.

The processing chamber 201, in which wafers 200, being substrates, are contained, is formed inside of the reaction tube 203 and the manifold 209. The boat 217, being a substrate holding tool, is constituted in the processing chamber 201 so as to be inserted from below. Inner diameters of the reaction tube 203 and the manifold 209 are made larger than a maximum outer shape of the boat 217 into which the wafers 200 are charged.

The boat 217 is constituted so as to hold a plurality of wafers 200 (for example 75 to 100 wafers) in an approximately horizontal state, at prescribed spaces (substrate pitch intervals) in multiple stages. The boat 217 is mounted on a heat insulating cap 218 for blocking heat conduction from the boat 217. The heat insulating cap 218 is supported from below by a rotation shaft 255. The rotation shaft 255 is provided so as to pass through the center part of the seal cap 219, while air-tightly maintaining the inside of the processing chamber 201. A rotation mechanism 267 for rotating the rotation shaft 255 is provided in a lower part of the seal cap 219. By rotating the rotation shaft 255 by the rotation mechanism 267, the boat 217 on which a plurality of wafers 200 are mounted, can be rotated, while air-tightly maintaining the inside of the processing chamber 201.

A heater 207, being a heating unit (heating mechanism) is provided concentrically with the reaction tube 203. The heater 207 is formed into a cylindrical shape, and is vertically installed by being supported by a heater base (not shown), being a holding plate.

### (Vaporized Gas Supply System)

A vaporized gas nozzle 233a, being a vaporized gas inlet part, is provided in the manifold 209. The vaporized gas nozzle 233a is formed into L-shape having a vertical portion and a horizontal portion. The vertical portion of the vaporized gas nozzle 233a is disposed in a vertical direction, along an inner wall of the reaction tube 203. A plurality of vaporized gas supply holes 248a are vertically formed on the side face of the vertical portion of the vaporized gas nozzle 233a. Opening diameters of the vaporized gas supply holes may be set to be the same extending from the lower part to the upper part, or may be set to be gradually larger from the lower part to the upper part. The horizontal portion of the vaporized gas nozzle 233a is provided so as to pass through the side wall of the manifold 209.

A vaporized gas supply tube 240a, being a vaporized gas supply system, for supplying vaporized gas into the processing chamber 201, is connected to a horizontal end portion (upstream side) of the vaporized gas nozzle 233a protruded from the side wall of the manifold 209. A vaporizer 260 is connected to the upstream side of the vaporized gas supply tube 240a, being the vaporized gas supply system. As shown in FIG. 3, the vaporizer 260 includes a pressure vessel 262. A vaporizing space 261 heated to a prescribed temperature atmosphere is formed inside of the pressure vessel 262. The liquid source is supplied into the vaporized space 261. An energizing heating heater 264 for heating the vaporized space 261 is provided on an outer periphery of the pressure vessel 262. When the vaporized space 261 is heated to a prescribed temperature atmosphere by the energizing heating heater 264, the liquid source supplied into the vaporized space 261 is vaporized, and the vaporized gas (source gas) is generated. An open/close valve 241a is provided in the vaporized gas supply tube 240a. By opening the open/close valve 241a, the vaporized gas generated by the vaporizer 260 is supplied into the processing chamber 201. In addition, a liquid filter 260f for allowing only pass of gas, while suppressing pass of liquid, is provided at a connecting spot 262d between the pressure vessel 262 and the vaporized gas supply tube 240a.

The vaporized gas supply system according to this embodiment is constituted mainly by the vaporized gas nozzle 233a, vaporized gas supply tube 240a, vaporizer 260, pressure vessel 262, vaporizing space 261, energizing heating heater 264, open/close valve 241a, connecting spot 262d, and liquid filter 260f.

### (Liquid Source Supply System and Carrier Gas Supply System)

A liquid source supply tube 240c, being a liquid source supply line, for supplying liquid source into the vaporizing space 261, a carrier gas supply tube 240f, being a carrier gas supply line, for supplying carrier gas into the vaporizing space 261, and a pressure meter 263 for measuring a pressure in the vaporizing space 261, are respectively connected to the upstream side of the vaporizer 260. A liquid source supply port 262a is constituted at the connecting spot between the pressure vessel 262 and the liquid source supply tube 240c, and a carrier supply port 262b is constituted at the connecting spot between the pressure vessel 262 and the carrier gas supply tube 240f, and a pressure meter connection port 262c is constituted at the connecting spot between the pressure vessel 262 and the pressure meter 263.

In addition, it is preferable to dispose the pressure meter connection port 262c at a position where the liquid source hardly invades into the pressure meter connection port 262c, and preferable to dispose it at a lower temperature part where the liquid source is hardly vaporized. Namely, it is preferable to constitute the pressure meter 263 so as to measure the pressure of a space adjacent to an area where the liquid source is thermally-decomposed. For example, it is preferable to provide the pressure meter connection port 262c between the liquid source supply port 262a and the carrier supply port 262b, and in the vicinity of the carrier support port 262b, for the purpose of suppressing a state that accurate and stable measurement of pressure is inhibited due to adhesion of source component (liquid source and vaporized gas) to the pressure meter 263.

The upstream side of the liquid source supply tube 240c as the liquid source supply line is connected to a liquid source supply tank 266 in which organic compounds such as TEMAH and TEMAZ are stored. The upstream side end portion of the liquid source supply tube 240c is immersed into the liquid source stored in the liquid source supply tank 266. Open/close valve 243c, liquid flow rate controller (LMFC) 242c, and open/close valve 241c, are provided in the liquid source supply tube 240c sequentially from the upstream side. Compressed gas supply tube 240d for supplying inactive gas such as He gas is connected to the upper surface of the liquid source supply tank 266. The upstream side of the compressed gas supply tube 240d is connected to a compressed gas supply source not shown for supplying inactive gas such as He gas, being the compressed gas. Open/close valve 241d is provided in the compressed gas supply tube 240d. By opening the open/close valve 241d, the compressed gas is supplied into the liquid source supply tank 266, and further by opening the open/close valve 243c and the open/close valve 241c, the liquid source in the liquid source supply tank 266 is supplied under compression into the vaporizing space 261. In addition, supply flow rate of the liquid source into the vaporizing space 261 (namely, flow rate of the vaporizing gas generated in the vaporizing space 261 and supplied into the processing chamber 201) can be controlled by the liquid flow rate controller 242c.

The upstream side of the carrier gas supply tube 240f, being the carrier gas supply line, is connected to a carrier gas supply source not shown for supplying inactive gas such as helium (He), neon (Ne), argon (Ar), and nitrogen (N₂), being the carrier gas. Flow rate controller (MFC) 242f and open/close valve 241f are provided in the carrier gas supply tube 240f sequentially from the upstream side. By opening the open/close valve 241f and the open/close valve 241a, the carrier gas is supplied into the vaporizing space 261, and mixed gas of the vaporized gas and the carrier gas is supplied into the processing chamber 201 via the vaporized gas supply tube 240a. By supplying the carrier gas into the vaporizing space 261, it is possible to urge discharge of the vaporized gas from the vaporizing space 261 and urge supply of the vaporized gas into the processing chamber 201. The supply flow rate of the carrier gas into the vaporizing space 261 (namely, the supply flow rate of the carrier gas into the processing chamber 201) can be controlled by the flow rate controller 242f. In addition, in this embodiment, even when the liquid source is not supplied into the vaporizing space 261 (even when the vaporized gas is not generated), a constant amount of carrier gas can be continued to be supplied into the vaporizing space 261 on a constant basis.

The liquid source supply system according to this embodiment is constituted mainly by the liquid source supply tube 240c, liquid source supply tank 266, open/close valve 243c, liquid flow rate controller (LMFC) 242c, open/close valve 241c, compressed gas supply tube 240d, open/close valve 241d, and liquid source supply port 262a. Also, the carrier gas supply system according to this embodiment is constituted mainly by the carrier gas supply tube 240f, flow rate controller (MFC) 242f, open/close valve 241f, carrier gas supply source not shown, and carrier gas supply port 242b.

### (Reactive Gas Supply System)

Reactive gas nozzle 233b, being a reactive gas inlet part, is provided in the manifold 209. The reactive gas nozzle 233b is formed into L-shape having the vertical portion and the horizontal portion. The vertical portion of the reactive gas nozzle 233b is disposed vertically along the inner wall of the reaction tube 203. A plurality of reactive gas supply holes 248b are vertically formed on the side face of the vertical portion of the reactive gas nozzle 233b. Opening diameters of the reactive gas supply holes 248b may be set to be the same extending from the lower part to the upper part respectively, or may be set to be gradually larger extending from the lower part to the upper part. The horizontal portion of the reactive gas nozzle 233b is provided so as to pass through the side wall of the manifold 209.

Reactive gas supply tube 240b, being a reactive gas supply system for supplying reactive gas into the processing chamber 201 is connected to the horizontal end portion (upstream side) of the reactive gas nozzle 233b protruded from the side wall of the manifold 209. Ozonizer 270 for generating ozone (O₃) (oxide gas), being the reactive gas, is connected to the upstream side of the reactive gas supply tube 240b, being the reactive gas supply system. Flow rate controller (MFC) 242b and open/close valve 241b are provided in the reactive gas supply tube 240b sequentially from the upstream side. Oxygen gas supply tube 240e is connected to the ozonizer 270. The upstream side of the oxygen gas supply tube 240e is connected to an oxygen gas supply source not shown for supplying oxygen (O₂) gas. Open/close valve 241e is provided in the oxygen gas supply tube 240e. By opening the open/close valve 241e, oxygen gas is supplied to the ozonizer 270, and by opening the open/close valve 241b, ozone gas generated by the ozonizer 270 is supplied into the processing chamber 201 through the reactive gas supply tube 240b. In Addition, the flow rate of the ozone gas into the processing chamber 201 can be controlled by the flow rate controller 242b.

The reactive gas supply system according to this embodiment is constituted mainly by the reactive gas nozzle 233b, reactive gas supply tube 240b, ozonizer 270, flow rate controller (MFC) 242b, open/close valve 241, oxygen gas supply tube 240e, oxygen gas supply source not shown, and open/close valve 241e.

### (Vent Tube)

The upstream side of the vaporizing gas vent tube 240i is connected between the vaporizer 260 and the open/close valve 241a in the vaporizing gas supply tube 240a. The downstream side of the vaporizing gas vent tube 240i is connected to the downstream side of the exhaust tube 231 as will be described later (between APC valve 231a and vacuum pump 231b as will be described later). Open/close valve 241i is provided in the vaporized gas vent tube 240i. By closing the open/close valve 241a and opening the open/close valve 241i, supply of the vaporized gas into the processing chamber 201 can be stopped, while generation of the vaporized gas by the vaporizer 260 is continued. Prescribed time is required for stably generating the vaporized gas. However, by switching operation of the open/close valve 241a and the open/close valve 241i, supply/stop of the vaporized gas into the processing chamber 201 can be switched in a short time.

Similarly, the upstream side of the reactive gas vent tube 240j is connected between the ozonizer 270 and the flow rate controller 242b in the reactive gas supply tube 240b. The downstream side of the reactive gas vent tube 240j is connected to the downstream side of the exhaust tube 231 (between the APC valve 231a and the vacuum pump 231b). Open/close valve 241j is provided in the reactive gas vent tube 240j. By closing the open/close valve 241b and opening the open/close valve 241j, supply of the ozone gas into the processing chamber 201 can be stopped, while generation of the ozone gas by the ozonizer 270 is continued. Prescribed time is required for stably generating the ozone gas. However, by switching operation of the open/close valve 241b and the open/close valve 241j, supply/stop of the ozone gas into the processing chamber 201 can be switched in a short time.

### (Purge Gas Supply Tube)

The downstream side of first purge gas tube 240g is connected to the downstream side of the open/close valve 241a in the vaporized gas supply tube 240a. A purge gas supply source not shown for supplying inactive gas such as N₂ gas, flow rate controller (MFC) 242g, and open/close valve 241g are provided in the first purge gas tube 240g, sequentially from the upstream side. By closing the open/close valve 241a and opening the open/close valve 241i and open/close valve 241g, supply of the vaporized gas into the processing chamber 201 can be stopped while generation of the vaporized gas is continued, and supply of the purge gas into the processing chamber 201 can be started. By supplying the purge gas into the processing chamber 201, discharge of the vaporized gas from the processing chamber 201 can be urged.

Similarly, the downstream side of second purge gas tube 240h is connected to the downstream side of the open/close valve 241b in the reactive gas supply tube 240b. The purge gas supply source not shown for supplying inactive gas such as N₂ gas, flow rate controller (MFC) 242h, and open/close valve 241h are provided in the second purge gas tube 240h sequentially from the upstream side. By closing the open/close valve 241b and opening the open/close valve 241j and open/close valve 241h, supply of the ozone gas into the processing chamber 201 can be stopped and supply of the purge gas into the processing chamber 201 can be started while generation of the ozone gas is continued. By supplying the purge gas into the processing chamber 201, discharge of the ozone gas from the processing chamber 201 can be urged.

### (Exhaust System)

The exhaust tube 231, being an exhaust system for exhausting the atmosphere in the processing chamber 201, is connected to the side wall of the manifold 209. Pressure sensor 245, being a pressure detector, APC (Auto Pressure Controller) valve 231a, being a pressure adjuster, and vacuum pump 231b, being a vacuum exhaust device, are provided in the exhaust tube 231 sequentially from the upstream side. By adjusting an opening degree of the open/close valve of the APC valve 242, with the vacuum pump 231b operated, the inside of the processing chamber 201 can be set to be a desired pressure.

The exhaust system according to this embodiment is constituted mainly by the exhaust tube 231, pressure sensor 245, APC valve 231a, and vacuum pump 231b.

### (Seal Cap)

The seal cap 219, being a furnace throat lid member, capable of air-tightly closing a lower end opening of the manifold 209 is provided in the lower part of the manifold 209. The seal cap 219 is brought into contact with the lower end of the manifold 209 from vertical lower side. The seal cap 219 is made of, for example, metal such as stainless, and is formed into a disc shape. O-ring 220b, being a seal member in contact with the lower end of the manifold 209 is provided on the upper surface of the seal cap 219. Rotation mechanism 267 for rotating the boat 217 is installed on the surface of the seal cap 219 on the opposite side of the processing chamber 201. The rotation shaft 255 of the rotation mechanism 267 is passed through the seal cap 219 to support the boat 217 from below, and by operating the rotation mechanism 267, the wafer 200 can be rotated. The seal cap 219 is vertically elevated by the boat elevator 215, being the elevation mechanism, disposed vertically outside of the reaction tube 203, and the boat 217 can thereby be conveyed to inside/outside of the processing chamber 201.

### (Controller)

Controller 280, being a control part (control unit) is connected to the heater 207, APC valve 231a, vacuum pump 231b, rotation mechanism 267, boat elevator 215, energizing heating heater 264, open/close valves 241a, 241b, 242c, 243c, 241d, 241e, 241f, 241g, 241h, 241i, 241j, liquid flow rate controller 242c, and flow rate controllers 242b, 242f, 242g, 242h. The controller 280 controls temperature adjustment operation of the heater 207, open/close and pressure adjustment of the APC valve 231a, start/stop of the vacuum pump 231b, rotation speed adjustment of the rotation mechanism 267, elevating operation of the boat elevator 215, open/close operation of the open/close valves 241a, 241b, 242c, 243c, 241d, 241e, 241f, 241g, 241h, 241i, and 241j, flow rate adjustment of the liquid flow rate controller 242c, and flow rate controllers 242b, 242f, 242g, and 242h.

Further, the controller 280 is connected to the pressure meter 263, so that a measured value of the pressure in the vaporizing space 261 can be received from the pressure meter 263. Moreover, the controller 280 controls the flow rate controller 242f so as to supply the carrier gas of the same flow rate into the vaporizing space 261 on a constant basis. Further, the controller 280 receives the measured value from the pressure meter 263, and when the received measured value is less than a prescribed pressure value, maintenance of the vaporizer 260 is judged to be unnecessary, and when the received measured value is more than the prescribed pressure value, maintenance of the vaporizer 260 is judged to be necessary. Such an operation will be described later.

### (4) Substrate Processing Step

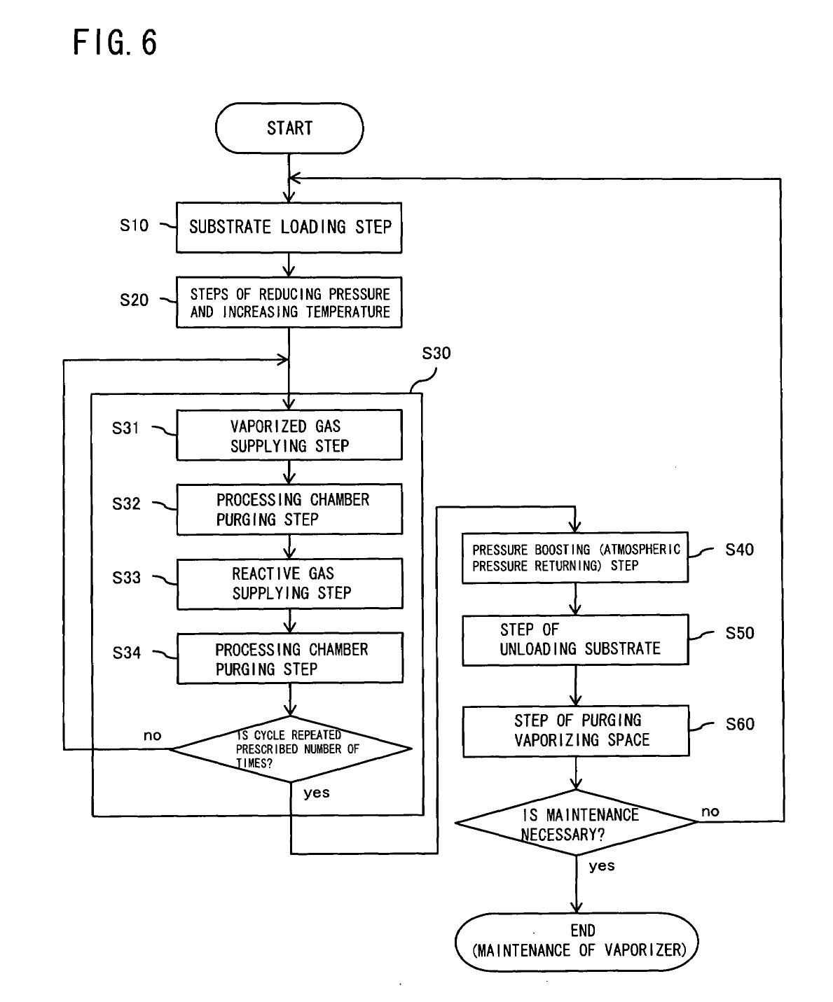

Subsequently, the substrate processing step according to an embodiment of the present invention will be described, with reference to FIG. 6. FIG. 6 is a flowchart showing the substrate processing step according to an embodiment of the present invention. Note that according to this embodiment, there is provided a method of forming the high dielectric constant film on the surface of the wafer 200 by using ALD method, being one of CVD (Chemical Vapor Deposition) methods, which is performed as one step of the manufacturing steps of the semiconductor device. Note that in the description given hereunder, the operation of each part constituting the substrate processing apparatus is controlled by the controller 280.

### (The Step of Loading Substrates (S10))

First, a plurality of wafers 200 are charged into the boat 217 (wafer charge). Then, the boat 217 holding the plurality of wafers 200 is elevated by the boat elevator 215 and is loaded into the processing chamber 201 (boat loading). In this state, the seal cap 219 is set in a state of sealing the lower end of the manifold 209 through the O-ring 220b. In the step of loading substrates (S10), preferably the open/close valve 241g and open/close valve 241h are opened and purge gas is continued to supplied into the processing chamber 201.

### (The Steps of Reducing Pressure and Increasing Temperature (S20))

Subsequently, the open/close valve 241g and the open/close valve 241h are closed, and the inside of the processing chamber 201 is exhausted by the vacuum pump 231b, so that the inside of the processing chamber 201 is set to be a desired pressure (vacuum degree) (S20). At this time, the pressure inside of the processing chamber 201 is measured by the pressure sensor 245, and based on this measured pressure, the opening degree of the APC valve 231a is feedback-controlled. Moreover, the inside of the processing chamber 201 is heated by the heater 207 so as to be set to a desired temperature (S20). At this time, power supply state to the heater 207 is feedback-controlled based on temperature information detected by the temperature sensor, so that the inside of the processing chamber 201 is set to have a desired temperature distribution. Then, the boat 217 is rotated by the rotation mechanism 267, to thereby rotate the wafer 200.

### (The Step of Forming a Film (S30))

Subsequently, the step of forming a film (S30) is executed. In the step of forming a film (S30), the step of supplying the vaporized gas onto the wafer 200 (S31) and the step of purging the inside of the processing chamber 201 (S32), the step of supplying the reactive gas onto the wafer 200 (S33), and the step of purging the inside of the processing chamber 201 are set as one cycle, and this cycle is repeated for prescribed number of times.

In the step of supplying the vaporized gas (S31), by opening the open/close valve 241d, the compressed gas is supplied into the liquid source supply tank 266. Then, by opening the open/close valves 243c and 241c, the liquid source in the liquid source supply tank 266 (Organic compounds such as TEMAH and TEMAZ) is sent (supplied) into the vaporizing space 261 under compression. Then, the vaporizing space 261 is heated so as to be a prescribed temperature atmosphere (for example 120° C. to 150° C.) by the energizing heating heater 264, and the liquid source supplied into the vaporizing space 261 is vaporized, to thereby generate the vaporized gas (source gas). In addition, by opening the open/close valve 241f, the carrier gas is supplied into the vaporizing space 261. The open/close valve 241a is closed and the open/close valve 241i is opened, until the vaporized gas is stably generated, and the mixed gas of the vaporized gas and the carrier gas is discharged from the vaporized gas vent tube 240i. When the vaporized gas is stably generated, the open/close valve 241i is closed and the open/close valve 241a are opened, to thereby supply the mixed gas of the vaporized gas and the carrier gas into the processing chamber 201. As a result, the mixed gas is supplied between laminated wafers 200, and gas molecules of the vaporized gas are adsorbed on the surface of the wafer 200. After supply of the mixed gas is continued for a prescribed time, the open/close valve 241a is closed and the open/close valve 241i is opened, to thereby stop supply of the mixed gas into the processing chamber 201 while generation of the vaporized gas is continued.

In the step of purging the inside of the processing chamber 201 (S32), the open/close valve 241g is opened and the purge gas is supplied into the processing chamber 201, to thereby urge discharge of the vaporized gas from the processing chamber 201. When the atmosphere in the processing chamber 201 is replaced with the purge gas, the open/close valve 241g is closed, to thereby stop supply of the purge gas into the processing chamber 201.

In the step of supplying the reactive gas onto the wafer 200 (S33), the open/close valve 241e is opened and oxygen gas is supplied to the ozonizer 270, to thereby generate the ozone gas, being the reactive gas. The open/close valve 241b is closed and the open/close valve 241j is opened until the reactive gas is stably generated, to thereby discharge the reactive gas from the reactive gas vent tube 240j. When the reactive gas is stably generated, the open/close valve 241j is closed, and the open/close valve 241b is opened, to thereby supply the reactive gas into the processing chamber 201. As a result, the reactive gas is supplied between the laminated wafers 200, then chemical reaction occurs between gas molecules of the vaporized gas adsorbed on the surface of the wafer 200, and the reactive gas, to thereby generate the high dielectric constant film (High-k film) containing Hf element and Zr element of one atomic layer to several atomic layers, on the surface of the wafer 200. After supply of the reactive gas is continued for a prescribed time, the open/close valve 241b is closed and the open/close valve 241j is opened, to thereby stop supply of the reactive gas into the processing chamber 201, while generation of the reactive gas is continued.

In the step of purging the inside of the processing chamber 201 (S34), by opening the open/close valve 241h, the purge gas is supplied into the processing chamber 201, to thereby urge discharge of the reactive gas and reaction products from the processing chamber 201. When the atmosphere in the processing chamber 201 is replaced with the purge gas, the open/close valve 241h is closed, to thereby stop supply of the purge gas into the processing chamber 201.

As described above, the step of supplying the vaporized gas onto the wafer 200 (S31) and the step of purging the inside of the processing chamber 201 (S34) are set as one cycle, and when the high dielectric constant film of a desired film thickness is formed on the wafer 200 by repeating this cycle for prescribed number of times, the step of forming a film (S30) is ended. Note that the pressure in the vaporizing space 261 in the step of forming a film (S30) is called a vaporization pressure. In the step of forming a film (S30), the liquid source is continuously or intermittently supplied into the vaporizing space 261 and the vaporized gas is generated as needed in the vaporizing space 261, and also switching of the open/close valves 241a and 241i is performed as needed. Therefore, the vaporization pressure becomes unstable. In addition, when the step of forming a film (S30) is executed (when the vaporized gas is generated by supplying the liquid source into the vaporizing space 261), residual matters containing carbon compound are generated in the vaporizer 260.

### (The Step of Boosting Pressure (S40), and the Step of Unloading Substrates (S50))

Subsequently, the opening degree of the APC valve 231a is set small, and the open/close valve 241g and the open/close valve 241h are opened, to thereby supply the purge gas into the processing chamber 201 until the pressure in the processing chamber 201 is set to atmospheric pressure (S40). Then, by the reversed procedure to the procedure of the step of loading substrates (S10), the already film-formed wafer 200 is unloaded from the processing chamber 201 (S50). In the step of unloading substrates (S50), preferably the purge gas is continued to be supplied into the processing chamber 201, by opening the open/close valve 241g and the open/close valve 241h.

### (Step of Purging Vaporizing Space (S60))

Subsequently, the step of purging vaporizing space (S60) is executed, for supplying only carrier gas into the vaporizing space 261, with no liquid source supplied into the vaporizing space 261.

In addition, in a conventional substrate processing step, steps of the step of loading substrates (S10) to the step of unloading substrates (S50) are set as one cycle, without executing the step of purging vaporizing space (S60), and this cycle is repeated. However, as described above, when the step of forming a film (S30) is executed, the residual matters containing carbon compound are generated in the vaporizer 260. Then, by repeatedly executing the step of forming a film (S30), the residual matters are accumulated inside of the vaporizer 260, thus causing clogging inside of the vaporizer 260, to boost the pressure inside of the vaporizing space 261, resulting in vaporization failure, thus inviting insufficient flow rate supplied into the processing chamber in some cases. Then, in the conventional substrate processing step, it is difficult to grasp an accumulation state (clogging state) of the residual matters without decomposing the vaporizer 260. Therefore, the timing of performing maintenance to the inside of the vaporizer 260 is lost, resulting in sudden reduction of the production yield in some cases.

According to the knowledge of the inventors of the present invention, the residual matters accumulated inside of the vaporizer 260 causes pressure boosting in the vaporizing space 261, and therefore by monitoring a variation of the pressure inside of the vaporizing space 261, the accumulation state of the residual matters can be grasped without decomposing the vaporizer 260. However, the pressure in the vaporizing space 261 in the step of forming a film (S30) is unstable, and therefore it is difficult to monitor a slight variation of the vaporization pressure, and difficult to accurately grasp the accumulation state of the residual matters.

Therefore, in the substrate processing step according to this embodiment, the step of purging vaporizing space (S60) is further executed, wherein only gas (carrier gas) is flown, and the variation of the pressure in the vaporizing space 261 is monitored, with the pressure (called base pressure) in the vaporizing space 261 made to be stabilized. Then, steps from the step of loading substrates (S10) to the step of purging vaporizing space (S60) are set as one cycle, and this cycle is repeated, and the variation of the pressure in the vaporizing space 261 is monitored in each repeated step of purging vaporizing space (S60), to thereby grasp the accumulation state of the residual matters. Note that the step of purging vaporizing space (S60) may be executed after the step of boosting pressure (S40) and the step of unloading substrates (S50) as shown in FIG. 6, or may be executed in parallel to the step of boosting pressure (S40) and the step of unloading substrates (S50) provided that the step of forming a film (S30) and the step of purging vaporizing space (S60) are alternately executed.

In the step of purging vaporizing space (S60), the open/close valve 241d, open/close valve 243c, and open/close valve 241c are closed, and the open/close valve 241f is opened, to thereby supply only carrier gas into the vaporizing space 261, with no liquid source supplied into the vaporizing space 261. Then, by opening at least any one of the valves of the open/close valve 243a and the open/close valve 243i, the carrier gas supplied into the vaporizing space 261 is exhausted from the vaporizing space 261. Also, in the repeatedly executed each step of purging vaporizing space (S60), the flow rate controller 242f is controlled so that the carrier gas supplied into the vaporizing space 261 is always set to be a constant amount and the same amount. As a result, the base pressure is stabilized to a prescribed pressure value according to the flow rate of the carrier gas, thus making it easy to detect a slight pressure variation in the vaporizing space 261 due to accumulation of the residual matters, and the accumulation state (clogging state) of the residual matters can be accurately grasped.

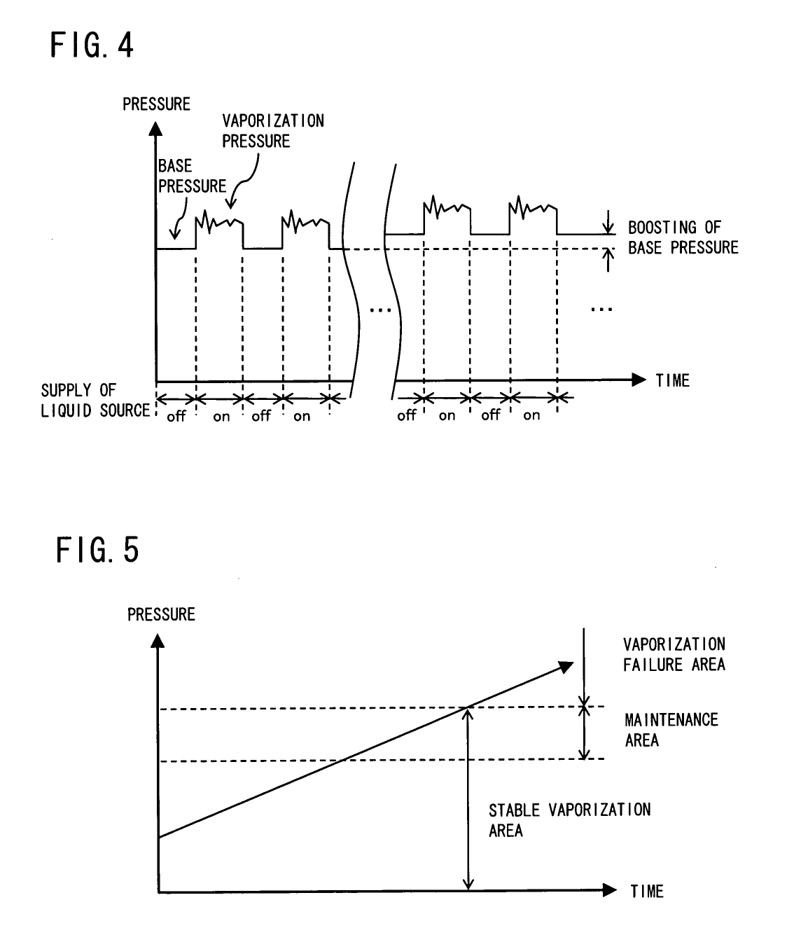

FIG. 4 is a graph chart exemplifying a state of the pressure variation in the vaporizing space 261, when the step of forming a film (S30) and the step of purging vaporizing space (S60) are alternately repeated. According to FIG. 4, it is found that by alternately repeating the step of forming a film (S30) and the step of purging vaporizing space (S60), the accumulation of the residual matters inside of the vaporizer 260 is advanced, and the pressure (base pressure and vaporization pressure) in the vaporizing space 261 is boosted. Here, the base pressure in the step of purging vaporizing space (S60) is relatively stable, while the vaporization pressure in the step of forming a film (S30) is unstable, and therefore it is found that boosting of the pressure can be easily monitored in a case of the base pressure. Namely, it is found that by monitoring the variation of the base pressure, the accumulation state of the residual matters can be easily grasped.

Then, in the step of purging vaporizing space (S60) according to this embodiment, a state of the vaporizer 260 is judged based on the measured value of the pressure meter 263 when only the carrier gas is supplied, with no liquid source supplied into the vaporizing space 261. Namely, when the measured value of the base pressure received from the pressure meter 263 is less than a prescribed pressure value, the maintenance of the vaporizer 260 is judged to be unnecessary, and when the measured value of the received base pressure is more than a prescribed pressure value, the maintenance of the vaporizer 260 is judged to be necessary”.

FIG. 5 is a graph chart exemplifying a relation between the pressure variation in the vaporizing space 261 and the state of the vaporizer 260. For example, as shown in FIG. 5, when the measured value of the base pressure is within a stable vaporization range and outside a maintenance range, maintenance of the vaporizer 260 is judged to be unnecessary for the present”, and when the measured value of the base pressure is within a stable vaporization range but within the maintenance range, it is judged that “it is time to perform maintenance to the vaporizer 260”, and when the measured value of the base pressure is within a vaporization failure range, it is judged that “maintenance of the vaporizer 260 is necessary”.

### (5) Advantage of this Embodiment

According to this embodiment, one or a plurality of advantages shown below are exhibited.

The substrate processing apparatus according to this embodiment includes a pressure meter 263 for measuring the pressure in the vaporizing space 261, and the controller 280 for receiving the measured value of the pressure from the pressure meter 263. Then, the controller 280 executes the step of purging vaporizing space (S60) by supplying only carrier gas into the vaporizing space 261, with no liquid source supplied into the vaporizing space 261, after the step of forming a film, and judges the state of the vaporizer 260 by monitoring the variation of the pressure (base pressure) in the vaporizing space 261 in the step of purging vaporizing space (S60). According to this structure, the accumulation state of the residual matters can be grasped without decomposing the vaporizer 260, and the timing of performing maintenance to the vaporizer 260 can be easily grasped in advance. Then, the maintenance of the vaporizer 260 can be systematically performed, and unfruitful cost by emergency response can be reduced.

Further, in the substrate processing apparatus according to this embodiment, when the step of purging vaporizing space (D60) is executed, by closing the open/close valve 241d, the open/close valve 243c, and the open/close valve 241c, and by opening the open/close valve 241f, only the carrier gas is supplied into the vaporizing space 261, with no liquid source supplied into the vaporizing space 261. Then, by opening at least either one of the open/close valve 243a and the open/close valve 243i, the carrier gas supplied into the vaporizing space 261 is exhausted from the vaporizing space 261. Also, in the substrate processing apparatus according to this embodiment, the flow rate controller 242f is controlled so that the flow rate of the carrier gas supplied into the vaporizing space 261 is always set to be a constant amount and the same amount, in repeatedly executed each step of purging vaporizing space (S60). According to such a structure, the base pressure is stabilized to a prescribed pressure value according to the flow rate of the carrier gas. Therefore, the slight pressure variation in the vaporizing space 261 due to accumulation of the residual matters can be easily detected, and the accumulation state of the residual matters can be accurately grasped.

In addition, in the substrate processing apparatus according to this embodiment, the state of the vaporizer 260 is judged based on the measured value of the pressure meter 263 when only the carrier gas is supplied into the vaporizing space 261, with no liquid source supplied into the vaporizing space 261, in the step of purging vaporizing space (S60). Namely, when the measured value of the base pressure received from the pressure meter 263 is less than a prescribed pressure value, maintenance of the vaporizer 260 is judged to be unnecessary, and when the received measured value of the base pressure is more than the pressure value, maintenance of the vaporizer 260 is judged to be necessary”. According to such a structure, the timing of performing maintenance to the inside of the vaporizer 260 can be easily grasped in advance, and sudden reduction of the production yield can be suppressed.

In the substrate processing apparatus according to this embodiment, the pressure meter connection port 262c can be disposed at a position where the liquid source hardly invades into the pressure meter connection port 262c, and can be disposed at a low temperature part where the liquid source is hardly vaporized. For example, the pressure meter connection port 262c can be provided between the liquid source supply port 262a and the carrier supply port 262b, and in the vicinity of the carrier supply port 262b. According to such a structure, the carrier gas is always flown in the vicinity of the pressure meter connection port 262c, and therefore the liquid source can hardly invade into the pressure meter connection port 262c. Moreover, the carrier support port 262b is disposed at a low temperature part (upstream side in the vaporizing space 261) where the liquid source is hardly vaporized. Therefore, the vaporized gas can hardly invade into the pressure meter connection port 262c. Namely, adhesion of a source component (liquid source and vaporized gas) to the pressure meter 263 can be suppressed, then pressure measurement can be accurately and stably performed, and the accumulation state of the residual matters can be accurately grasped.

### Other Embodiment of the Present Invention>

In the aforementioned embodiment, the step of forming a film (S30) and the step of purging vaporizing space (S60) are alternately repeated. However, the present invention is not limited thereto.

For example, the step of purging vaporizing space (S60) may be performed together with the steps of purging the inside of the processing chamber 201 (S32 and S34), when these steps are performed. In such a case, in the steps of purging the inside of the processing chamber 201 (S32 and S34) (the step of purging vaporizing space (S60)), by closing the open/close valve 241d, the open/close valve 243c, and the open/close valve 241c, and by opening the open/close valve 241f, only the carrier gas is supplied into the vaporizing space 261, with no liquid source supplied into the vaporizing space 261. Then, by opening the open/close valve 243a, the carrier gas supplied into the vaporizing space 261 is supplied into the processing chamber 201 as purge gas.

Then, the variation of the pressure in the vaporizing space 261 is monitored, and the accumulation state of the residual matters in the vaporizing space 261 is grasped.

Also, similarly, the step of purging vaporizing space (S60) may be performed together with the step of supplying the reactive gas onto the wafer 200 (S33) when this step is performed. In such a case, in the step of supplying the reactive gas onto the wafer 200 (S33) (the step of purging vaporizing space (S60)), the open/close valve 241d, open/close valve 243c, open/close valve 241c are closed, and the open/close valve 241f is opened, to thereby supply only the carrier gas into the vaporizing space 261, with no liquid source supplied into the vaporizing space 261. Then, by opening the open/close valve 243i, the carrier gas supplied into the vaporizing space 261 is discharged from the vaporizing gas vent tube 240i. Then, the variation of the pressure in the vaporizing space 261 is monitored, and the accumulation state of the residual matters in the vaporizing space 261 is grasped.

In the aforementioned embodiment, explanation has been given for a case that the vaporized gas obtained by vaporizing the liquid source is supplied into the processing chamber 201, and the high dielectric film is formed on the wafer 200. However, the present invention is not limited thereto. For example, even when the vaporized gas obtained by vaporizing a solid source and a source, with the solid source solved in a solvent, is supplied into the processing chamber 201 and the high dielectric film (high dielectric constant film) such as BST film, STO film, and PZT film is formed on the wafer 200, the present invention can be suitably applied. Namely, even when judging the state of the vaporizer for vaporizing the solid source and the source, with the solid source solved in the solvent, the present invention can be suitably applied. In such a case, only the carrier gas is supplied into the vaporizing space of the vaporizer without supplying the solid source and the source, with the solid source solved in the solvent, then the pressure in the vaporizing space is monitored by the pressure meter, while stabilizing the pressure in the vaporizing space, and the pressure in the vaporizing space is monitored by the pressure meter, to thereby judge the state of the vaporizer. In addition, when the vaporizing state of the source is desired to be monitored, the source is supplied into the vaporizing space, and whether or not the source is stably vaporized is confirmed.

In the aforementioned embodiment, explanation has been given for a case of executing ALD method of alternately supplying the vaporized gas and the reactive gas onto the wafer 200. However, the present invention is not limited thereto. Namely, as long as using the vaporized gas obtained by vaporizing the liquid source, solid source and source, with the solid source solved in the solvent, for example, even when other method such as CVD (Chemical Vapor Deposition) method, etc, is executed, the present invention can be suitably applied. Further, the present invention is not limited to a case of forming the high dielectric constant film, and can be suitably applied to the substrate processing apparatus forming other film such as a nitride film, an oxide film, a metal film, and a semiconductor film by using the vaporizer, and the manufacturing method of the semiconductor device.

### Preferred Aspects of the Present Invention

Preferred aspects of the present invention will be additionally described hereinafter.

According to an aspect of the present invention, there is provided a substrate processing apparatus, including:

a processing chamber in which substrates are contained;

a vaporizer having a vaporizing space, for generating vaporized gas by vaporizing liquid source supplied into the vaporizing space;

a liquid source supply system having a liquid source supply line for supplying the liquid source into the vaporizing space;

a vaporized gas supply system having a vaporized gas supply line for supplying the vaporized gas into the processing chamber;

an exhaust system for exhausting an atmosphere in the processing chamber;

a pressure meter for measuring a pressure in the vaporizing space;

a carrier gas supply system having a carrier gas supply line for supplying carrier gas into the vaporizing space; and

a controller for judging a state of the vaporizer based on a measured value of the pressure meter when the carrier gas is supplied into the vaporizing space.

Preferably, when the sate of the vaporizer is judged, only the carrier gas is supplied into the vaporizing space.

Also preferably, the pressure meter is disposed at a low temperature part in the vaporizing space where the liquid source is hardly vaporized.

Also preferably, the pressure meter is provided between the liquid source supply line and the carrier gas supply line, and at a position closer to the carrier gas supply line.

Also preferably, the substrate processing apparatus has:

an inactive gas supply line connected to the liquid source supply line at a connecting spot between the vaporizer and the processing chamber;

a filter installed between the connecting spot and the processing chamber in the liquid source supply line; and

a second pressure meter installed on the inactive gas supply line.

According to another aspect of the present invention, there is provided a manufacturing method of a semiconductor device, including the steps of:

forming a film by supplying vaporized gas generated by supplying liquid source into a vaporizing space, onto substrates contained in a processing chamber;

purging the vaporizing space by supplying carrier gas into the vaporizing space, with no liquid source supplied into the vaporizing space,

with these steps repeated alternately,

wherein in each of the repeated step of purging vaporizing space, pressure in the vaporizing space is measured while the carrier gas of the same flow rate is supplied into the vaporizing space, and when a measured value of the pressure is less than a prescribed pressure value, maintenance of the vaporizer is judged to be unnecessary, and when the measured value of the pressure is more than the prescribed pressure value, the maintenance of the vaporizer is judged to be necessary.

According to further another aspect of the present invention, there is provided a manufacturing method of a semiconductor device, including the steps of:

loading substrates into a processing chamber;

reducing pressure in the processing chamber;

increasing temperature of the substrates;

forming a film by supplying vaporized gas generated by supplying liquid source into a vaporizing space, to the substrates contained in the processing chamber;

boosting pressure in the processing chamber;

unloading the substrates to outside the processing chamber; and

measuring pressure in the vaporizing space, while supplying carrier gas, with no liquid source supplied into the vaporizing space.

Preferably, the step of measuring pressure is performed before the step of unloading substrate.

Also preferably, the steps from the step of loading substrates to the step of adjusting pressure are sequentially repeated, and a pressure variation in the vaporizing space is monitored, and when a measured value of the pressure is less than a prescribed pressure value, maintenance of the vaporizer is judged to be unnecessary, and when the measured value of the pressure is more than the prescribed pressure value, the maintenance of the vaporizer is judged to be necessary.

According to further another aspect of the present invention, there is provided a substrate processing apparatus, including:

a processing chamber in which substrates are contained;

a vaporizer having a vaporizing space heated to a prescribed temperature atmosphere, for generating vaporized gas by vaporizing liquid source supplied into the vaporizing space;

a supply system for supplying vaporized gas generated by the vaporizer into the processing chamber;

an exhaust system for exhausting an atmosphere in the processing chamber;

a pressure meter for measuring a pressure in the vaporizing space;

a carrier gas supply line for supplying carrier gas into the vaporizing space; and

a controller for judging a state of the vaporizer based on a measured value of the pressure meter when only the carrier gas is supplied into the vaporizing space, with no liquid source supplied into the vaporizing space.

According to further another aspect of the present invention, there is provided a substrate processing apparatus, including:

a processing chamber in which substrates are contained;

a vaporizer having a vaporizing space heated to a prescribed temperature atmosphere, for generating vaporized gas by vaporizing liquid source supplied into the vaporizing space;

a supply system for supplying vaporized gas generated by the vaporizer into the processing chamber;

an exhaust system for exhausting an atmosphere in the processing chamber;

a pressure meter for measuring a pressure in the vaporizing space;

a carrier gas supply line for supplying carrier gas into the vaporizing space; and

a controller for controlling operations of the supply system, the carrier gas supply line, and the exhaust system, and connected so as to receive a measured value from the pressure meter, wherein

the controller alternately repeats

the step of forming a film by supplying the vaporized gas generated by supplying liquid source into the vaporizing space, onto substrates contained in the processing chamber from the vaporizing space; and

the step of purging vaporizing space by supplying only the carrier gas, with no liquid source supplied into the vaporizing space, and

in each of the repeated step of purging vaporizing space, a measured value is received from the pressure meter, while the carrier gas of the same flow rate is supplied into the vaporizing space on a constant basis, and

when the received measured value is less than a prescribed pressure value, maintenance of the vaporizer is judged to be unnecessary, and when the received measured value is more than the prescribed pressure value, the maintenance of the vaporizer is judged to be necessary.

Preferably, the pressure meter is disposed at a position where the pressure meter and the liquid source are hardly brought into contact with each other, or is disposed at a low temperature part in the vaporizing space where liquid source is hardly vaporized. Further preferably, the pressure meter is provided between a liquid source supply line for supplying the liquid source into the vaporizing space and the carrier gas supply line, and in the vicinity of the carrier gas supply line.

According to further another aspect of the present invention, there is provided a manufacturing method of a semiconductor device, including the steps of

forming a film by supplying vaporized gas generated by supplying liquid source into a vaporizing space heated to a prescribed temperature atmosphere, onto substrates contained in a processing chamber;

purging vaporizing space by supplying only carrier gas into the vaporizing space, with no liquid source supplied into the vaporizing space,

with these steps repeated alternately,

wherein in each of the repeated step of purging vaporizing space,

pressure in the vaporizing space is measured, while the carrier gas of the same flow rate is supplied into the vaporizing space on a constant basis, and

when a measured value of the pressure is less than a prescribed pressure value, maintenance of the vaporizer is judged to be unnecessary, and when the measured value of the pressure is more than the prescribed value, the maintenance of the vaporizer is judged to be necessary.

1. A substrate processing apparatus, including:
a processing chamber in which substrates are contained;
a vaporizer having a vaporizing space, for generating vaporized gas by vaporizing liquid source supplied into the vaporizing space;
a liquid source supply system having a liquid source supply line for supplying the liquid source into the vaporizing space;
a vaporized gas supply system having a vaporized gas supply line for supplying the vaporized gas into the processing chamber;
an exhaust system for exhausting an atmosphere in the processing chamber;
a pressure meter for measuring a pressure in the vaporizing space;
a carrier gas supply system having a carrier gas supply line for supplying carrier gas into the vaporizing space; and
a controller for judging a state of the vaporizer based on a measured value of the pressure meter when the carrier gas is supplied into the vaporizing space.

2. The substrate processing apparatus according to claim 1, wherein when a state of the vaporizer is judged, only the carrier gas is supplied into the vaporizing space.

3. The substrate processing apparatus according to claim 1, wherein the pressure meter is disposed at a low temperature part in the vaporizing space where the liquid source is hardly vaporized.

4. The substrate processing apparatus according to claim 1, wherein the pressure meter is disposed between the liquid source supply line and the carrier gas supply line, and at a position closer to the carrier gas supply line.

5. The substrate processing apparatus according to claim 1, comprising:
an inactive gas supply line connected to the liquid source supply line at a connecting spot between the vaporizer and the processing chamber;
a filter disposed between the connecting spot on the liquid source supply line and the processing chamber; and
a second pressure meter installed on the inactive gas supply line.

6. A manufacturing method of a semiconductor device, comprising the steps of:
forming a film by supplying vaporized gas generated by supplying liquid source into a vaporizing space, to substrates contained in a processing chamber;
purging the vaporizing space by supplying carrier gas into the vaporizing space, with no liquid source supplied into the vaporizing space,
with these steps repeated alternately,
wherein in each of the repeated step of purging vaporizing space, pressure in the vaporizing space is measured while the carrier gas of the same flow rate is supplied into the vaporizing space, and when a measured value of the pressure is less than a prescribed pressure value, maintenance of the vaporizer is judged to be unnecessary, and when the measured value of the pressure is more than the prescribed pressure value, the maintenance of the vaporizer is judged to be necessary.

7. A manufacturing method of a semiconductor device, comprising the steps of:
loading substrates into a processing chamber;
reducing a pressure in the processing chamber;
increasing a temperature of the substrates;
forming a film by supplying vaporized gas generated by supplying liquid source into a vaporizing space, to the substrates contained in the processing chamber;
boosting the pressure in the processing chamber;
unloading the substrates to outside the processing chamber; and
measuring the pressure in the vaporizing space while supplying carrier gas into the vaporizing space, with no liquid source supplied into the vaporizing space.

8. The manufacturing method of the semiconductor device according to claim 7, wherein the step of measuring pressure is performed before the step of unloading substrates.

9. The manufacturing method of the semiconductor device according to claim 7, wherein steps from the step of loading substrates to the step of adjusting pressure are sequentially repeated, then a pressure variation in the vaporizing space is monitored, and when a measured value of the pressure is less than a prescribed pressure value, maintenance of the vaporizer is judged to be unnecessary, and when the measured value of the pressure is more than the prescribed value, the maintenance of the vaporizer is judged to be necessary.
